(19) United States
(12) Patent Application Publication
(10) Pub. No.: US 2015/0340209 A1
(43) Pub. Date: Nov. 26, 2015

(54) FOCUS RING REPLACEMENT METHOD FOR A PLASMA REACTOR, AND ASSOCIATED SYSTEMS AND METHODS

(71) Applicant: Micron Technology, Inc., Boise, ID (US)

(72) Inventor: Michael E. Koltonski, Boise, ID (US)

(73) Assignee: MICRON TECHNOLOGY, INC., Boise, ID (US)

(21) Appl. No.: 14/282,532

(22) Filed: May 20, 2014

(51) Int. Cl. H01J 37/32; H01L 21/677; H01L 21/67

(52) U.S. Cl. CPC H01J 37/32743; H01J 37/32715; H01J 37/32642; H01J 37/32899; H01L 21/67069; H01L 21/67739

(57) ABSTRACT

A focus ring replacement method for a plasma reactor, and associated systems and methods are disclosed herein. In one embodiment, a plasma processing system includes a plasma reactor and a wafer handler. The plasma reactor includes a processing chamber defining an enclosure and having a chamber opening accessible to the enclosure. A wafer holder assembly is positioned within the enclosure and configured to hold a semiconductor wafer and a focus ring that surrounds the semiconductor wafer. The wafer handler is configured to transport the focus ring through the chamber opening, and the wafer holder assembly is further configured to transfer the focus ring between the wafer handler and the wafer holder assembly.

### TECHNICAL FIELD

The present technology relates to semiconductor processing equipment, and in particular, to a method for replacing focus rings in a plasma reactor.

### BACKGROUND

Plasma reactors can be used in the manufacture of semiconductor devices for etching a pattern into a semiconductor wafer. Plasma reactors typically include a processing chamber containing a wafer chuck that carries the wafer and an electrode located above the wafer. The chuck and the electrode can apply radio frequency (RF) energy in the presence of a process gas to form a plasma. The plasma, in turn, produces a boundary region adjacent the wafer that drives reactants (e.g., ionized reactants) toward the wafer to physically and/or chemically remove (e.g., etch) material from the wafer.

One challenge in plasma reactors is process uniformity. In particular, when the distribution of reactants is non-uniform at the boundary region, the etch rate will likewise be non-uniform. To improve uniformity, a focus ring is often placed around the wafer on the wafer chuck. The focus ring is designed to alter the distribution of reactants at the outer portion of the wafer to counterbalance the reactant distribution at the inner portion of the wafer. The reactants, however, also etch the material of the focus ring (e.g., quartz, silicon, silicon carbide focus ring), and thus process uniformity over time as the focus ring degrades. Focus rings accordingly have a limited lifetime and need to be replaced periodically. Although considerable work and research has been done to develop more etch resistant focus rings, the results to date have been mixed.

### BRIEF DESCRIPTION OF THE DRAWINGS

FIG. 1 is a top plan view illustrating a plasma processing system configured in accordance with an embodiment of the present technology.

FIG. 2 is an enlarged, top plan view of a plasma chamber of the plasma processing system of FIG. 1.

FIGS. 3A-3C are cross-sectional side views showing selected stages in which a degraded focus ring is removed from a wafer holder assembly in accordance with several embodiments of the present technology.

FIGS. 4A and 4B are cross-sectional side views showing a replacement focus ring being installed on a wafer holder assembly in accordance with several embodiments of the present technology.

### DETAILED DESCRIPTION

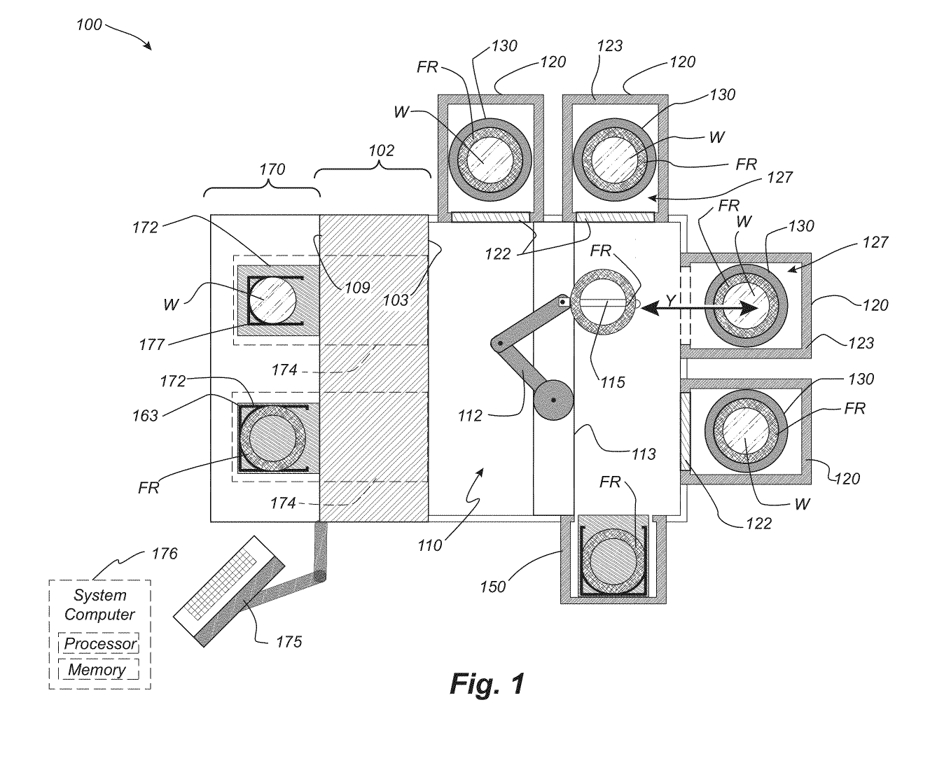

Specific details of several embodiments of focus ring replacement methods for plasma reactors and associated systems and methods are described below. The plasma reactors described herein can be employed in the manufacture of semiconductor devices formed on a semiconductor wafer. Such semiconductor devices can include any of a variety of integrated circuits (e.g., memory, logic, controllers, etc.), laser diodes, and/or microelectromechanical systems (MEMS), to name a few. The term “wafer” refers to a semiconductor substrate that can be used to form semiconductor devices. For example, a wafer can be a generally circular silicon substrate having a diameter of, e.g., 150 mm, 200 mm, 300 mm, or more. In other embodiments, other types of substrates, including non-circular substrates, can be used to form semiconductor devices. Further, although described in the context of material removal processes (i.e., etching), plasma reactors configured in accordance with the various embodiments of the present technology can be used for other types of processes (e.g., film deposition). A person skilled in the relevant art will also understand that the technology may have additional embodiments, and that the technology may be practiced without several of the details of the embodiments described below with reference to FIGS. 1-4B.

As used herein, the terms “vertical,” “lateral,” “upper” and “lower” can refer to relative directions or positions of features of a plasma processing system in view of the orientation shown in the Figures. For example, “upper” or “uppermost” can refer to a feature positioned closer to the top of a page than another feature. These relative directions or positions, however, should be construed broadly to include other orientations, such as being inverted when applicable.

FIG. 1 is a top plan view illustrating a plasma processing system 100 (“processing system 100”) configured in accordance with an embodiment of the present technology. As shown, the processing system 100 includes an airlock 102 having a low pressure side 103 and a high pressure side 109, a transfer station 110 at the low pressure side 103, and a loading station 170 at the high pressure side 109. The processing system 100 includes a plurality of plasma reactors 120 accessible from the transfer station 110. The plasma reactors 120 each include a processing chamber 123 defining an enclosure 127, and a wafer holder assembly, or wafer chuck 130, within the enclosure 127. As shown, the wafer chuck 130 can hold a semiconductor wafer “W” and a focus ring “FR” surrounding the wafer. The wafer chuck 130 can also function as an electrode contact for forming a plasma in the processing chamber 123, such as a plasma for plasma etching the wafer. The processing chamber 123 can also include a chamber door 122 that provides access to the transfer station 110.

The transfer station 110 is located between the plasma reactors 120 and the airlock 102, and the processing system 100 further includes a wafer handler 112 centrally positioned within the transfer station 110 and slidably coupled to a track or rail 113. The wafer handler 112 is configured to transport wafers on the end effector 115 between the airlock 102 and the individual plasma reactors 120 for processing. In the illustrated embodiment, for example, the wafer handler 112 can insert an end effector 115 into the processing chamber 123, as shown by the double-sided arrow Y. The wafer handler 112 can also use the end effector 115 to transport focus rings. In particular, the wafer handler 112 can transport used focus rings (e.g., degraded focus rings) from the processing chamber 123 and transport replacement focus rings (e.g., new focus rings) to the processing chamber 123. In one embodiment described in greater detail below, the wafer handler 112 can also transport focus rings to and from a focus ring storage region, or storage compartment 150.

The loading station 170 has one or more loading regions 172 configured to receive wafer carriers 177 (e.g., a wafer cassette or pod) containing one or more wafers for loading/unloading the wafers into/from in the plasma reactors 120. The airlock 102 can include one or more conveyors 174 (e.g., wafer cassette movers) for transporting wafers to and from the transfer station 110 through the airlock 102. In another embodiment, a robotic arm can be used in addition to or in lieu of the conveyors 174. In an alternate embodiment, the conveyors 174 can be omitted, and an operator can manually load and unload wafers directly at the airlock 102. Once the wafers are in the airlock 102, the airlock 102 is closed and the air pressure in the air lock 102 is reduced to the pressure level of the transfer station 110. For example, the airlock 102 can lower pressure from atmospheric pressure (e.g., about 760 Torr) to vacuum (e.g., about 0 Torr). Once the airlock 102 is at a suitable low pressure level, the airlock 102 opens and the wafer handler 112 transports the wafers individually from the airlock 102 into one of the plasma reactors 120. After processing is completed, the wafer handler 112 can return the wafers to the airlock 102 until they are ready to be transferred back to the loading station 170. In some embodiments, the transfer station 110 can include a holding region (not shown) for temporarily holding wafers in the transfer station 110 and outside of the airlock 102 so that other wafers can move through the airlock 102.

In several embodiments, the processing system 100 can also include a system controller or system computer 176 (shown schematically). The system computer 176 can include a processor and a memory storing processing instructions for controlling the plasma reactors 120, the wafer handler 112, and sub-systems and other components of the processing system 100. The system computer 176 can also provide an interface (e.g., a computer terminal 175) for an operator to monitor processing in the plasma reactors 120, select plasma processing parameters or programs, perform system maintenance, and/or carry out other operations of the processing system 100. Although not shown for purposes of clarity, the processing system 100 can also include other components, such as power supplies and counter electrodes for producing RF energy; motor controllers for operating the wafer handler 112 and conveyors 174; and conduits, manifolds, and valves for supplying process gases.

In several aspects of the illustrated embodiment of FIG. 1, an operator can also load/unload focus rings at the loading station 170. Similar to the wafers, the conveyors 174 can transport focus rings (individually or collectively) through the airlock 102. In one embodiment, the focus rings can be transferred individually through the airlock 102. In another embodiment, the conveyors 174 can transport a focus ring carrier 163 through the airlock 102. The focus ring carrier 163 can be similar in structure and function as the wafer carrier 177, but is configured to hold focus rings instead of wafers. The wafer handler 112 can then transport the focus rings between the airlock 102 and the plasma reactors 120. As described in greater detail below, the wafer chuck 130 in the processing chamber 123 can be configured to transfer a used focus ring from the wafer chuck 130 to the end effector 115 for removal and to transfer a replacement focus ring from the end effector 115 to the wafer chuck 130 for replacement.

In another aspect of this embodiment, the wafer handler 112 can store focus rings at the storage compartment 150 accessible from the transfer station 110 under vacuum. For example, the storage compartment 150 can be used to store multiple used focus rings and/or multiple replacement focus rings. In one embodiment, the wafer handler 112 can transport one or more replacement focus rings to the storage compartment 150 for temporary storage until they are needed to replace a degraded focus ring. In another embodiment, the wafer handler 112 can transport degraded focus rings to the storage compartment 150 until they ready to be returned to the transfer station 110 via the airlock 102. In these and other embodiments, the storage compartment 150 can facilitate the automatic or semi-automatic replacement of focus rings in the plasma reactors 120. For example, in some embodiments the system computer 176 can store a maintenance program in which the wafer handler 112 is instructed to deposit a used focus ring in the storage compartment 150 and also to draw a replacement focus ring from the storage compartment 150. In several of these embodiments, the program can be based on a preventive maintenance schedule that replaces a focus ring after it has been used for a certain number of RF hours.

In many plasma reactors systems, preventative maintenance routines typically require that the focus rings be replaced every 700 to 1000 RF hours. Typically, the processing chamber is vented so that a technician can open the processing chamber to access and replace the focus ring. Once the focus ring is replaced, the technician closes the chamber and restores vacuum. In general, the step of installing the focus ring itself is not substantially time consuming. However, a considerable amount of time is needed to restore vacuum and to re-qualify the processing chamber for processing. For example, the overall downtime needed for restoring vacuum and then re-qualifying the chamber can take one to two days. This downtime can create processing bottlenecks and reduce the throughput of a plasma reactor. Moreover, opening the chamber can expose the plasma reactor to contaminants in the ambient environment outside of the processing chamber. Plasma reactors configured in accordance with several embodiments of the present technology, however, can address these and other limitations of conventional plasma reactors For example, because the wafer handler 112 can replace focus rings while still under vacuum, the plasma reactors 120 do not need to be vented, nor do they need to be opened to the ambient environment. As such, processing downtime and tool contamination can be reduced.

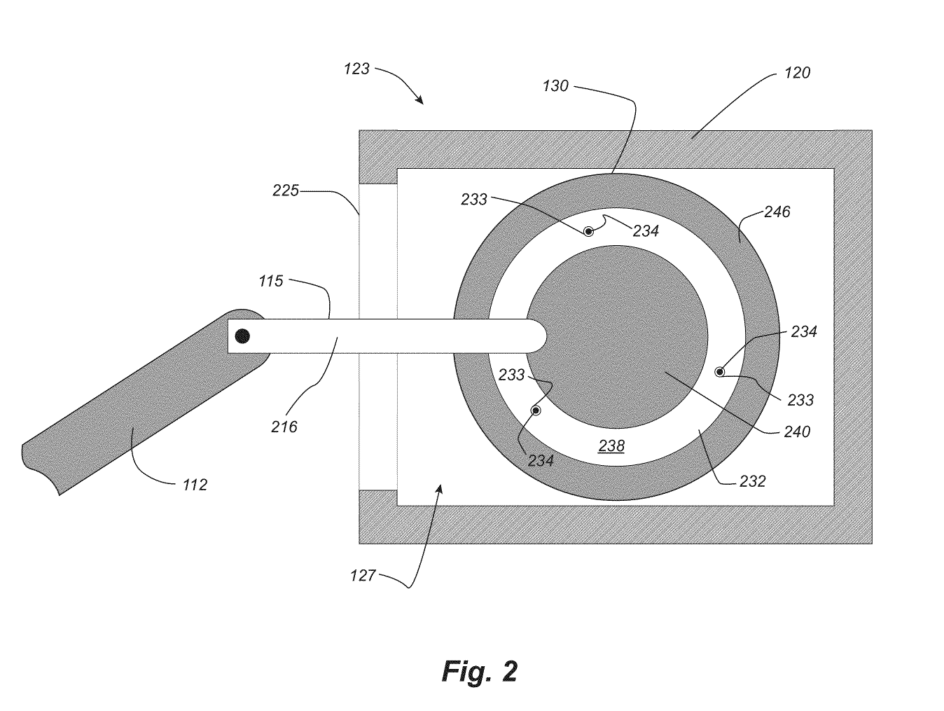

FIG. 2 is an enlarged, top plan view of the processing chamber 123 of one of the plasma reactors 120 of the processing system 100 of FIG. 1. As shown, the chamber door 122 (FIG. 1) is moved to open a chamber slot 225 through which the end effector 115 can be inserted into the enclosure 127. In several embodiments, the end effector 115 can include an elongate and generally flat support member 216. In some embodiments, the end effector 115 can be similar to a conventional end effector used for carrying semiconductor wafers, but the end effector 115 can be longer than a conventional end effector to accommodate the relatively larger diameter of a focus ring.

As further shown in FIG. 2, the wafer chuck 130 includes a wafer platform 240 for carrying a wafer (not shown) and a focus ring platform 232 for carrying a focus ring (not shown) around the wafer. In the illustrated embodiment, the focus ring platform 232 is recessed below the wafer platform 240 and located between the wafer platform 240 and a guide member 246. The focus ring platform 232 includes a mounting surface 238 and a plurality of apertures 233 disposed radially along the mounting surface 238. A plurality of mechanically actuated (e.g., pneumatically or spring-actuated) lift members, or lift pins 234, are positioned within the corresponding apertures 233 of the focus ring platform 232.

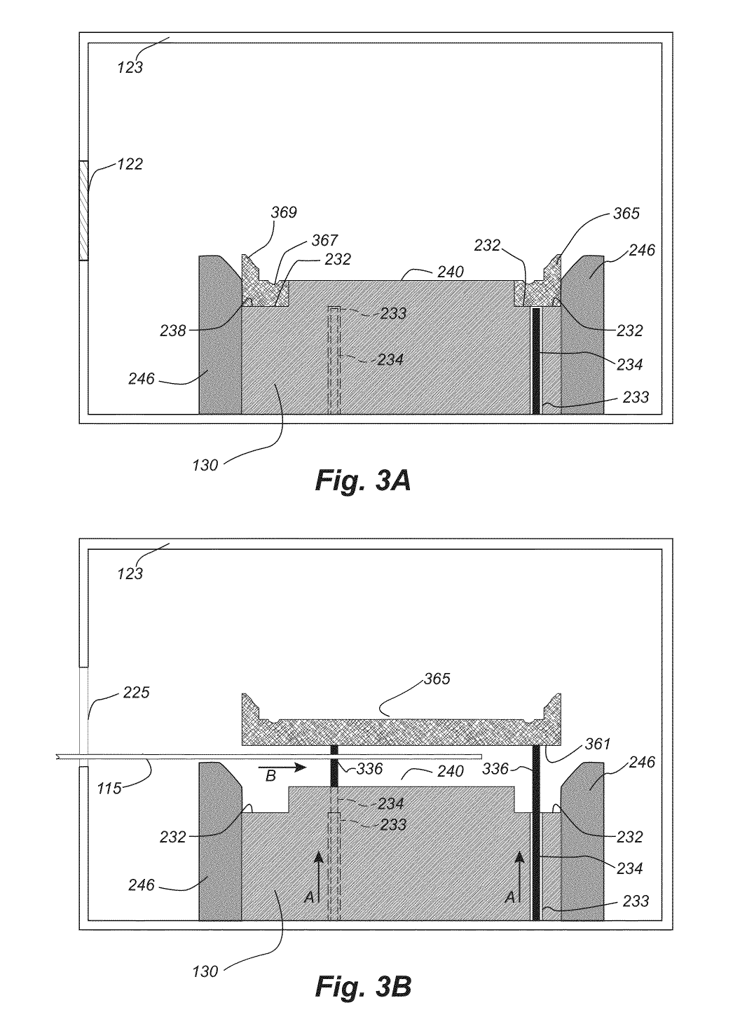

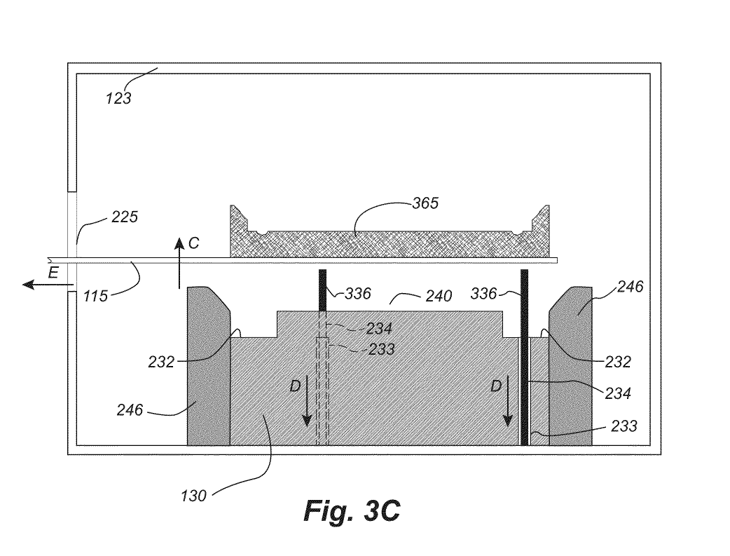

FIGS. 3A-3C are cross-sectional side views showing stages in which a degraded focus ring 365 is removed from the wafer chuck 130 in accordance with selected embodiments of the present technology. Referring to FIG. 3A, the focus ring 365 is seated on the mounting surface 238 of the focus ring platform 232 and secured between the wafer platform 240 and the guide member 246. Also, the lift pins 234 are in a retracted position within the apertures 233. As shown, the focus ring 365 has a degraded region 367 that has been formed by plasma reactants (not shown) etching the material of the focus ring 365 over time. The plasma reactants have also degraded an outer wall portion 369 of the focus ring 365.

Referring to FIG. 3B, the lift pins 234 have moved into a raised position and lifted the focus ring 365 above the wafer platform 240. As shown, end portions 336 of the lift pins 234 can move vertically upward through the apertures 233 (as shown by arrows A) and into contact with a back-side surface 361 of the focus ring 365. Further movement of the lift pins 234 can raise the focus ring 365 to a suitable height that allows the end effector 115 to move laterally beneath the focus ring 365 (as shown by arrow B). The chamber door 122 (FIG. 3A) is then opened, and the wafer handler 112 (FIG. 1) moves the end effector 115 laterally through the chamber slot 225 and partially into the processing chamber 123.

Referring to FIG. 3C, the focus ring 365 has been transferred from the lift pins 234 to the end effector 115. In the illustrated embodiment, the wafer handler 112 moves the end effector 115 vertically upward (as shown by arrow C) to lift the focus ring 365 off of the lift pins 234. In an alternate embodiment, the lift pins 234 moves vertically downward to lower the focus ring 365 onto the end effector 115 (i.e., rather than the end effector lifting the focus ring). In either case, once the focus ring 365 is transferred to the end effector 115, the lift pins 234 retract (as shown by arrows D) until the end portions 336 of the lift pins 234 are at or below the apertures 233. At the same time, the wafer handler 112 moves the end effector 115 laterally away from the chuck 130 and through the chamber slot 225 (as shown by arrow E). Once the focus ring 365 is outside of the processing chamber 123, the wafer handler 112 can transport the focus ring 365 to the storage compartment 150 (FIG. 1) for storage or directly to the airlock 102 (FIG. 1) for removal at the loading station 170 (FIG. 1)

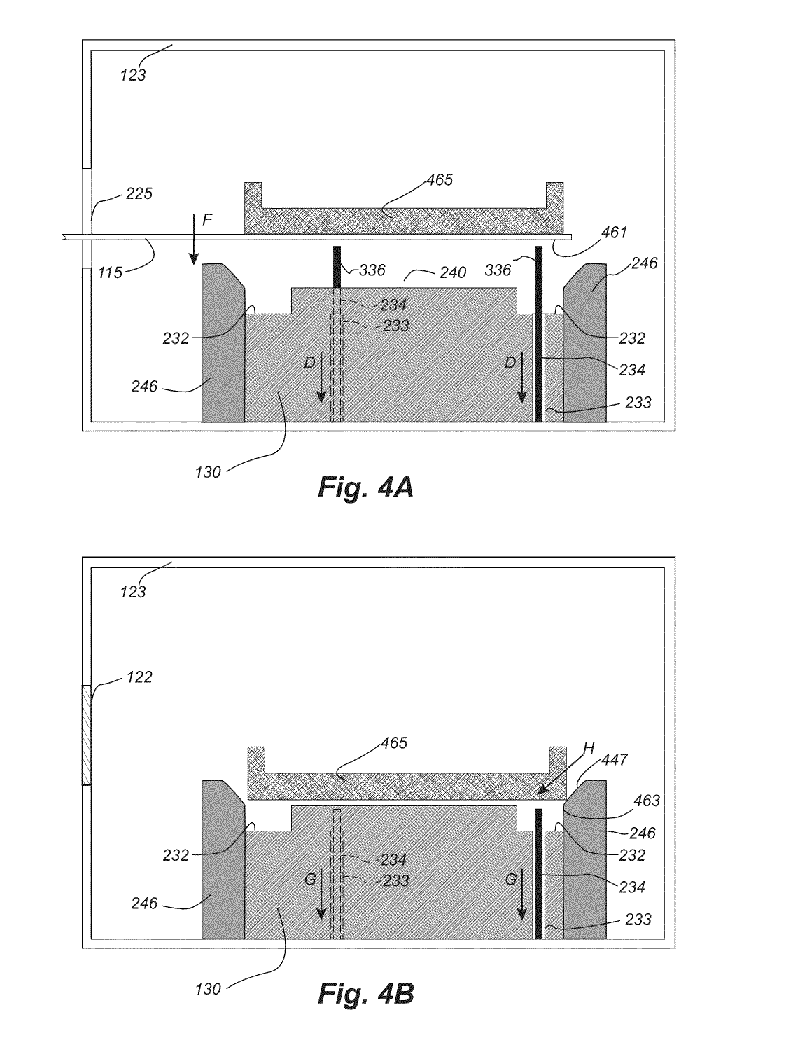

FIGS. 4A and 4B are cross-sectional side views showing a replacement focus ring 465 being installed on the wafer chuck 130 in accordance with selected embodiments of the present technology. Referring to FIG. 4A, the end effector 115 with the replacement focus ring 465 been inserted through the chamber slot 225 to position the focus ring 465 above the wafer chuck 130. In the illustrated embodiment, the wafer handler 112 (FIG. 1) can move the end effector 115 vertically downward (as shown by arrow F) and place the focus ring 465 on the end portions 336 of the lift pins 234. In another embodiment, however, the lift pins 234 can move vertically upward until the end portions 336 lift the focus ring off 465 of the end effector 115.

Referring to FIG. 4B, the wafer handler 112 has moved the end effector 115 (FIG. 4A) outside of the processing chamber 123, and the lift pins 234 have lowered the focus ring 465 to an intermediary height above the focus ring platform 232. As shown, an outer edge portion 463 of the focus ring 465 contacts one region of the guide member 246 at a sloped surface 447 inclined toward the focus ring platform 232. As the lift pins 234 continue to move downwardly toward the focus ring platform 232 (as shown by arrows G), the outer edge portion 463 slides along the sloped surface 447 toward the focus ring platform 232 (as shown by arrow H). The sloped surface 447 continues to guide the movement of the focus ring 465 until it is centered on the focus ring platform 232. In one aspect of this embodiment, the guide member 246 properly seats the focus ring 465 on the focus ring platform 232 to ensure that the back-side surface 461 contacts the mounting surface 238. Once the focus ring 465 is seated on the focus ring platform 232, the processing chamber 122 is tested or qualified for plasma processing. For example, a test wafer (not shown) can be loaded and etched to evaluate that an etch rate is within a suitable range.

From the foregoing, it will be appreciated that specific embodiments of the technology have been described herein for purposes of illustration, but that various modifications may be made without deviating from the spirit and scope of the various embodiments of the present technology. For example, although the wafer chucks 130 of the illustrated embodiments are shown as having three lift pins 234, the wafer chucks 130 can include more than three lift pins (e.g., five pins, tens pins, fifteen pins, or more). In addition, the storage compartment 150 (FIG. 1) can be positioned differently, such as between individual plasma reactors 120 and/or at a different side of the transfer station 110. Moreover, because many of the basic structures and functions of plasma processing systems are known, they have not been shown or described in further detail to avoid unnecessarily obscuring the described embodiments. Further, while various advantages and features associated with certain embodiments of the new technology have been described above in the context of those embodiments, other embodiments may also exhibit such advantages and/or features, and not all embodiments need necessarily exhibit such advantages and/or features to fall within the scope of the disclosure.

I/we claim:

1. A plasma processing system, comprising:
a plasma reactor, including—
a processing chamber defining an enclosure and having a chamber opening accessible to the enclosure, and
a wafer holder assembly within the enclosure and configured to hold a semiconductor wafer and a focus ring that surrounds the semiconductor wafer; and
a wafer handler configured to transport the focus ring through the chamber opening,
wherein the wafer holder assembly is further configured to transfer the focus ring between the wafer holder assembly and the wafer handler.

2. The plasma processing system of claim 1 wherein the wafer handler includes an end effector, and wherein the wafer handler is configured to carry the focus ring on the end effector.

3. The plasma processing system of claim 2 wherein the wafer holder assembly includes:
a wafer platform;
a focus ring platform surrounding the wafer platform; and
a plurality of lift members configured to lift the focus ring into an elevated position above the wafer platform.

4. The plasma processing system of claim 1, further comprising an airlock having a low pressure side and a high pressure side, wherein the wafer handler is at the low pressure side of the airlock, and wherein the wafer handler is configured to transport the focus ring between the airlock and the plasma reactor.

5. The plasma processing system of claim 1, further comprising a focus ring storage region, wherein the wafer handler is configured to transport the focus ring between the focus ring storage region and the plasma reactor.

6. The plasma processing system of claim 1, further comprising:
a loading station;
a transfer station housing the wafer handler; and
an airlock separating the loading station from the transfer station,
wherein the loading station is configured to load the focus ring into the transfer station.

7. The plasma processing system of claim 6 wherein the loading station is configured to load a plurality of focus rings contained in a focus ring carrier.

8. A plasma reactor, comprising a wafer holder assembly, wherein the wafer holder assembly includes:
a wafer platform;
a focus ring platform recessed relative to the wafer platform and configured to carry a focus ring; and
a plurality of lift members disposed radially along the focus ring platform, wherein the lift members are configured to lift the focus ring relative to the wafer platform.

9. The plasma reactor of claim 8, further comprising a plurality of apertures extending through the focus ring platform, wherein each of the apertures contains a corresponding one of the lift members.

10. The plasma reactor of claim 9 wherein the lift members each include a mechanically actuated lift pin.

11. The plasma reactor of claim 8, further comprising a processing chamber defining an enclosure and configured to receive an end effector into the enclosure, wherein the lift members are configured to hold the focus ring above the end effector when the end effector is inserted into the enclosure.

12. The plasma reactor of claim 8 wherein the lift members are further configured to lower the focus ring unto the focus ring platform.

13. The plasma reactor of claim 12, further comprising a guide member surrounding the focus ring platform, wherein the guide member is configured to center the focus ring when the lift members lower the focus ring unto the focus ring platform.

14. The plasma reactor of claim 13 wherein the guide member includes a sloped surface inclined toward the focus ring platform and configured to guide an outer edge portion of the focus ring toward the focus ring platform when the lift members lower the focus ring unto the focus ring platform.

15. A method for replacing focus rings in a plasma processing system, the method comprising:
inserting an end effector into an enclosure of a plasma reactor; and
transferring a focus ring between a wafer holder assembly and the end effector.

16. The method of claim 15 wherein inserting the end effector includes transporting the focus ring on the end effector through a chamber opening in the plasma reactor.

17. The method of claim 16 wherein transferring the focus ring includes:
elevating the focus ring above a wafer platform; and
inserting the end effector between the wafer platform and the elevated focus ring.

18. The method of claim 16 wherein transferring the focus ring includes:
receiving the focus ring from the end effector onto a plurality of lift members; and
lowering the focus ring onto a focus ring platform via the lift members.

19. The method of claim 15, further comprising transporting the focus ring between the plasma reactor and an airlock via end effector.

20. The method of claim 15, further comprising transporting the focus ring between the plasma reactor and a focus ring storage region via the end effector.
